(19) United States
(12) Patent Application Publication
(10) Pub. No.: US 2014/0009895 A1
(43) Pub. Date: Jan. 9, 2014

(54) CHIP CARD HOLDING MECHANISM AND ELECTRONIC DEVICE USING THE SAME

(71) Applicants: Hon Hai Precision Industry Co., Ltd., New Taipei (TW); Fu Tai Hua Industry (Shenzhen) Co., Ltd., Shenzhen (CN)

(72) Inventor: HUI WANG, Shenzhen (CN)

(21) Appl. No.: 13/913,513

(22) Filed: Jun. 10, 2013

(30) Foreign Application Priority Data
Jul. 6, 2012 (CN) 2012102334031

(51) Int. Cl. H05K 7/14

(52) U.S. Cl. CPC H05K 7/1461
USPC 361/737

(57) ABSTRACT

An electronic device includes a housing and a chip card holding mechanism mounted on the housing. The housing defines an insert opening. The chip card holding mechanism includes a tray received in the insert opening, a transferring assembly and a driving assembly mounted on the housing. The tray comprises base body and an operating portion located at an end of the base body. The operating portion includes a resisting surface. The transferring assembly includes a rotating member and a positioning shaft. The positioning shaft is positioned on the housing. The rotating member is rotatably sleeved on the positioning shaft. The rotating member includes a transferring end and a resisting end. The driving assembly resists the transferring end, and the resisting end resists the resisting surface of the operating portion of the tray.

### BACKGROUND

1. Technical Field

The present disclosure relates to holding mechanisms, and particularly, to a chip card holding mechanism and an electronic device using the same.

2. Description of Related Art

Portable electronic devices such as mobile phones and tablet computers may employ at least one chip card (e.g., SIM card) for handling or performing multiple functions such as storing information, connecting to the internet, dialing calls, for example. It is necessary to provide a chip card holding mechanism for holding/securing the chip card within the portable electronic device. When detaching or replacing the chip card, a user must detach an outer cover from the portable electronic device first, thereby exposing the chip card holding mechanism, thus making the removal and replacement of the chip card inconvenient. In addition, known or conventional chip card holding mechanisms have complex structures, and the chip card holding mechanisms may not unlock if the pressure is not sufficient to rotate a holding member thereof.

Therefore, there is room for improvement in the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views.

FIG. 1 is a partial, isometric view of an embodiment of an electronic device comprising a housing and a resisting member.

FIG. 2 is a partial, exploded view of the electronic device in FIG. 1.

FIG. 3 is similar to FIG. 2, but view in another aspect.

FIG. 4 is an isometric view of the resisting member shown in FIG. 1.

FIG. 5 is similar to FIG. 1, but omitting the housing.

FIG. 6 is another partially assembled isometric view of the electronic device shown in FIG. 1.

FIG. 7 is a partial, isometric view of the electronic device in a use state.

### DETAILED DESCRIPTION

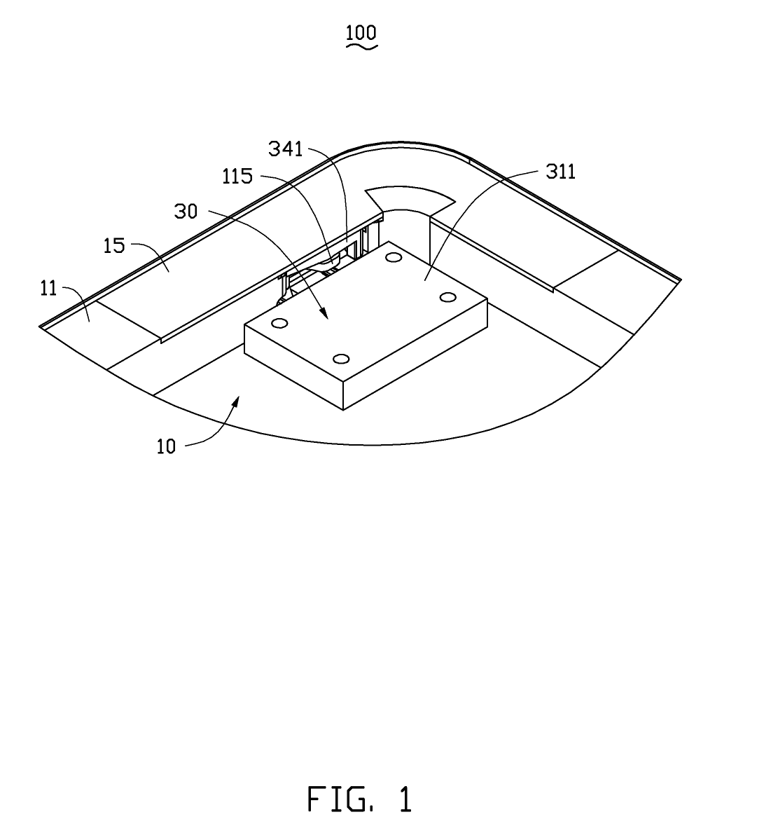

FIG. 1 shows an electronic device 100 of an embodiment. The electronic device 100 includes a housing 10 (partially being shown in FIG. 1) and a chip card holding mechanism 30 mounted in the housing 10 for holding a chip card (not shown). The portable electronic device 100 includes various modules for performing specific functions. However, for the sake of simplicity, only the modules related to the chip card holding mechanism 30 are described and illustrated. The portable electronic device 100 may be a mobile phone, a tablet computer, or other electronic device. The chip card may be one of various types of cards, such as an SD Card, a multimedia card (MMC Card), or a SIM Card. In an illustrated embodiment, the portable electronic device 100 is a tablet computer, and the chip card is a SIM card.

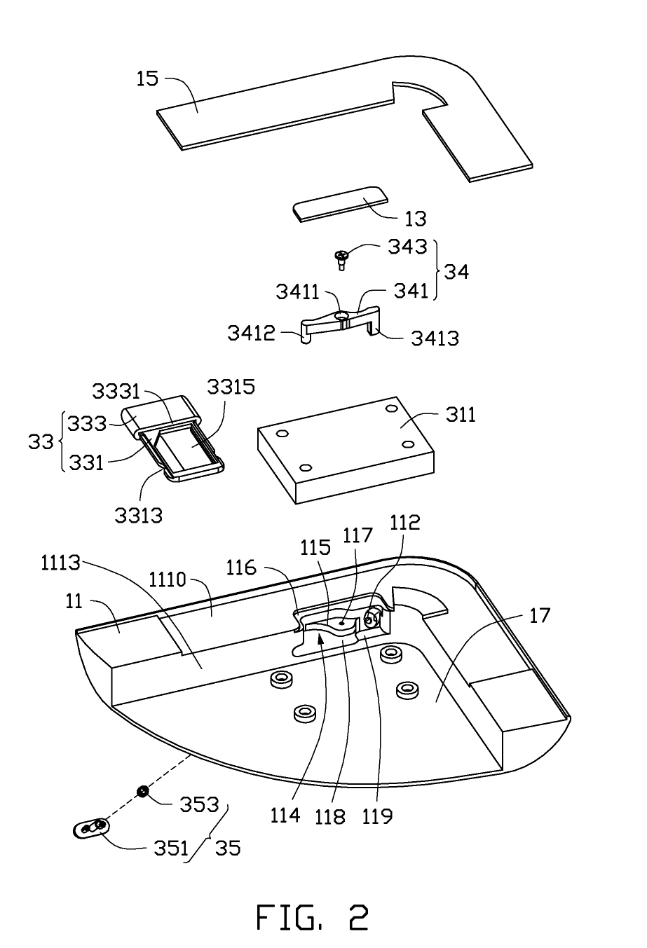

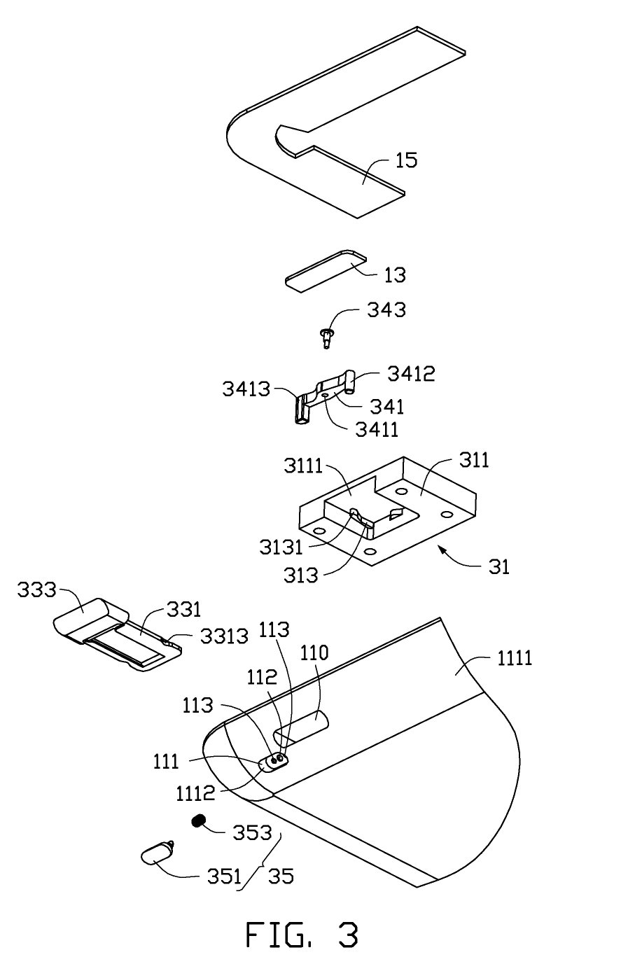

FIGS. 2 and 3 show that the housing 10 includes a main body 11 (partially being shown in FIGS. 2 and 3), a first blocking sheet 13, and a second blocking sheet 15. The first blocking sheet 13 and the second blocking sheet 15 are mounted on the main body 11. The main body 11 defines a receiving chamber 17, for containing various modules of the electronic device 100, such as a SIM card connector (not shown). An outer sidewall 1111 of the main body 11 defines an insert opening 110 (shown in FIG. 3), and a receiving groove 111 (shown in FIG. 3) adjacent to the insert opening 110. The insert opening 110 and the receiving groove 111 are substantially strip-shaped. A bottom wall 1112 of the receiving groove 111 defines a through hole 112 and at least one positioning hole 113 arranged apart. In the illustrated embodiment, there are two positioning holes 113 positioned at opposite sides of the through hole 112 (one positioning hole 113, which is labeled, is substantially blocked from view by the housing 10, and is partially shown in FIG. 3).

An inner sidewall 1113 of the main body 11 defines an indent 114 corresponding to a position of the receiving groove 111 and the insert opening 110. The indent 114 communicates with the insert opening 110, the through hole 112, and the positioning hole 113. A first protruding portion 115 and a second protruding portion 116 protrude outwardly from a sidewall of the indent 114 along a direction perpendicular to the inner sidewall 1113 of the main body 11. The first protruding portion 115 and the second protruding portion 116 are received in the indent 114. The first protruding portion 115 is located above the insert opening 110, and the second protruding portion 116 is located above the first protruding portion 115. A protruding length of the first protruding portion 115 is larger than a protruding length of the second protruding portion 116. The first protruding portion 115 defines a restricting hole 117. In the illustrated embodiment, the restricting hole 117 is a blind hole. In an alternative embodiment, the restricting hole 117 may be a through hole.

A bottom surface of the indent 114 includes a first support surface 118 and a second support surface 119 connecting with the first supporting surface 118. The first supporting surface 118 and the second supporting surface 119 are planar surfaces. In the illustrated embodiment, the second supporting surface 119 is closer to the first protruding portion 115 than that of the first supporting surface 118. In an alternative embodiment, the first supporting surface 118 may be coplanar with the second supporting surface 119. The main body 11 defines a mounting groove 1110 at a top surface thereof. The first blocking sheet 13 is mounted on the second protruding portion 116. The second blocking sheet 15 is mounted in the mounting groove 1110. The first blocking sheet 13 and the second blocking sheet 15 partially cover the indent 114.

The chip card holding mechanism 30 is slidably assembled in the housing 10, and includes a latching assembly 31, a tray 33, a transferring assembly 34, and a driving assembly 35.

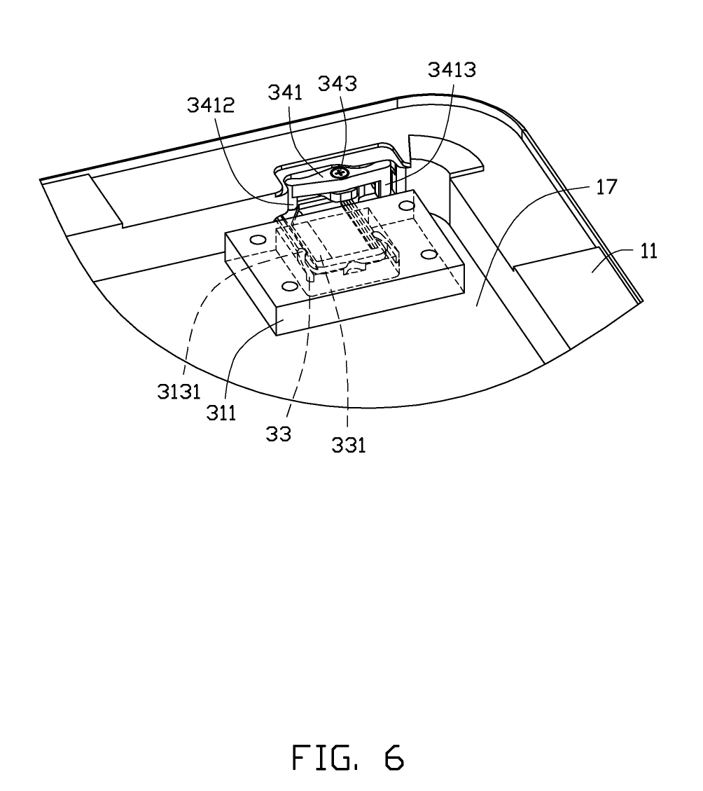

The latching assembly 31 is configured to latch with the tray 33. The latching assembly 31 is mounted in the receiving chamber 17, and is located adjacent to the indent 114. The latching assembly 31 includes a fastening member 311 and a pair of elastic latching members 313 (shown in FIG. 6) mounted on the fastening member 311. The fastening member 311 is substantially cubic, and is mounted on the bottom surface of the receiving chamber 17. A sidewall of the fastening member 311 adjacent to the indent 114 defines a containing groove 3111, for partially receiving the tray 33. The containing groove 3111 communicates with the indent 114. The pair of elastic latching members 313 respectively protrude from opposite ends of a bottom surface of the containing groove 3111, and a gap exists between each of the elastic latching members 313 and the corresponding sidewall of the containing groove 3111. Each elastic latching member 313 forms a latching portion 3131 at a distal end thereof, for latching with the tray 33.

The tray 33 includes a base body 331 and an operating portion 333 connected to an end of the base body 331. The base body 331 is slidably mounted on the first supporting surface 118 of the housing 10, and an end thereof away from the operating portion 333 is received in the containing groove 3111 of the fastening member 311. The base body 331 defines a pair of latching grooves 3313 at opposite sidewalls, for receiving and latching with the latching portions 3131 of the elastic latching members 313. The base body 331 further defines a chip card receiving groove 3315, for receiving the chip card. A shape and a size of the operating portion 333 match with those of the insert opening 110, and the operating portion 333 is received in the insert opening 110. The operating portion 333 includes a resisting surface 3331 adjacent to the base body 331.

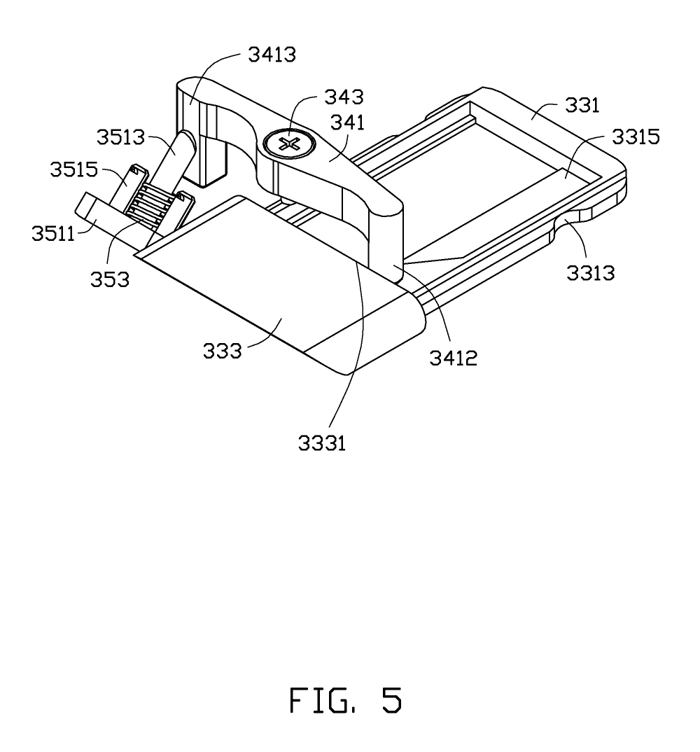

FIGS. 2, 3, 5, and 6 show that the transferring assembly 34 is rotatably mounted on the first protruding portion 115, and received in the indent 114. The transferring assembly 34 includes a rotating member 341 and a positioning shaft 343. The rotating member 341 is sleeved on the positioning shaft 343, and is capable of rotating around the positioning shaft 343. The rotating member 341 is mounted on the first protruding portion 115 through the positioning shaft 343, and defines an insert hole 3411. The insert hole 3411 of the rotating member 341 is aligned with the restricting hole 117 of the first protruding portion 115. The rotating member 341 includes a resisting end 3412 and a transferring end 3413. The resisting end 3412 and the transferring end 3413 are located at two opposite distal ends of the rotating member 341. The resisting end 3412 is located above the base body 331 of the tray 33, and is positioned corresponding to the insert opening 110. The resisting end 3412 is configured to resist the resisting surface 3331 of the operating portion 333 (shown in FIG. 5). The transferring end 3413 is located above the second supporting surface 119, and is positioned corresponding to the through hole 112. The positioning shaft 343 is inserted into the insert hole 3411 and the restricting hole 117, and is fixed into the restricting hole 117, thus the rotating member 341 is capable of rotating around the positioning shaft 343. In the illustrated embodiment, the positioning shaft 343 is a screw.

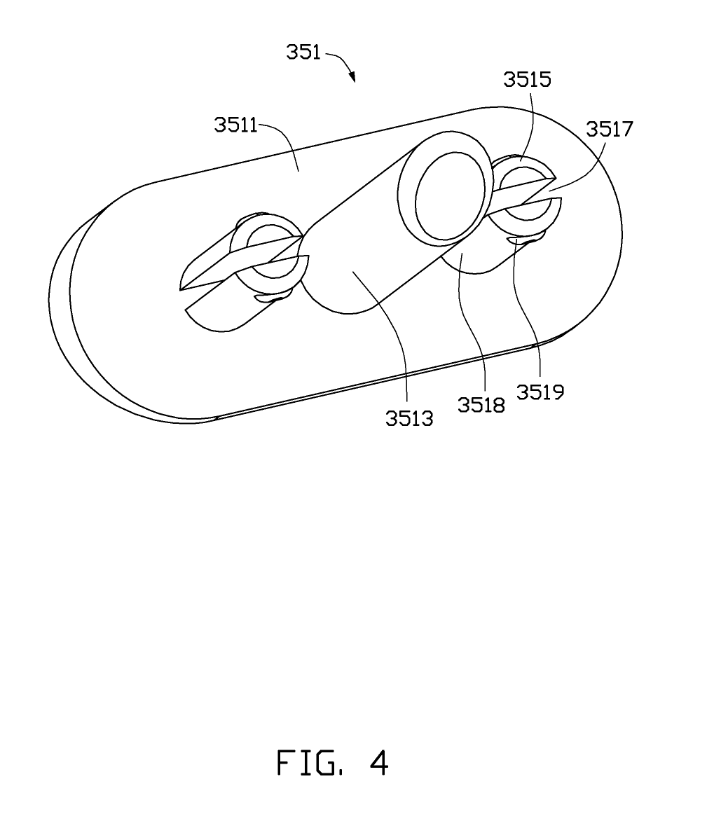

The driving assembly 35 includes a pushing member 351 and an elastic member 353. The pushing member 351 is received in the receiving groove 111, and is configured to push the transferring end 3413 of the rotating member 341. Referring also to FIG. 4, the pushing member 351 includes a pressing portion 3511, a pushing portion 3513, and two positioning portions 3515. The pushing portion 3513 and the positioning portions 3515 protrude from a sidewall of the pressing portion 3511. The two positioning portions 3515 are located at two sides of the pushing portion 3513. The pressing portion 3511 matches with and is received in the receiving groove 111. The pushing portion 3513 passes through the through hole 112, and resists the transferring end 3413 of the rotating member 341 (shown in FIG. 5). The positioning portions 3515 are inserted into the two positioning holes 113, for positioning the pushing member 351 into the receiving groove 111.

The positioning portion 3515 is substantially cylindrical, and defines an opening 3517 (shown in FIG. 4) at one end thereof away from the pressing portion 3511 along an axis. Two posts 3519 protrude from an outer sidewall 3518 of the positioning portion 3515, respectively, and are positioned at two opposite sides of the opening 3517. Because the positioning portion 3515 defines the opening 3517, thus when the positioning portion 3515 is inserted into the positioning holes 113, the positioning portion 3515 deforms and the posts 3519 radially resist a sidewall of the positioning hole 113, and the positioning portion 3515 is thereby positioned in the positioning hole 113. The elastic member 353 is sleeved on the pushing portion 3513. Two ends of the elastic member 353 resist the pressing portion 3511 and a bottom wall of the receiving groove 111, respectively. In the illustrated embodiment, the elastic member 353 is a spring.

FIG. 6 shows that in assembly, the rotating member 341 is first mounted onto the first protruding portion 115 through the positioning shaft 343. The positioning shaft 343 is inserted into the insert hole 3411 and the restricting hole 117, and is fixed within the restricting hole 117. Second, the fastening member 311 is positioned within the receiving chamber 17, and is positioned adjacent to the indent 114. Third, the tray 33 is inserted into the insert opening 110, and the base body 331 is received in the containing groove 3111. The latching portions 3131 of the elastic latching members 313 are latched with the latching grooves 3313, respectively. Fourth, the elastic member 353 is sleeved on the pushing portion 3513, and then the pushing member 351 is inserted into the receiving groove 111. The pushing portion 3513 passes through the through hole 112, and resists the transferring end 3413. The positioning portions 3515 are inserted into the positioning hole 113. Finally, the first blocking sheet 13 is assembled on the second protruding portion 116, and the second blocking sheet 15 is assembled on the mounting groove 1110.

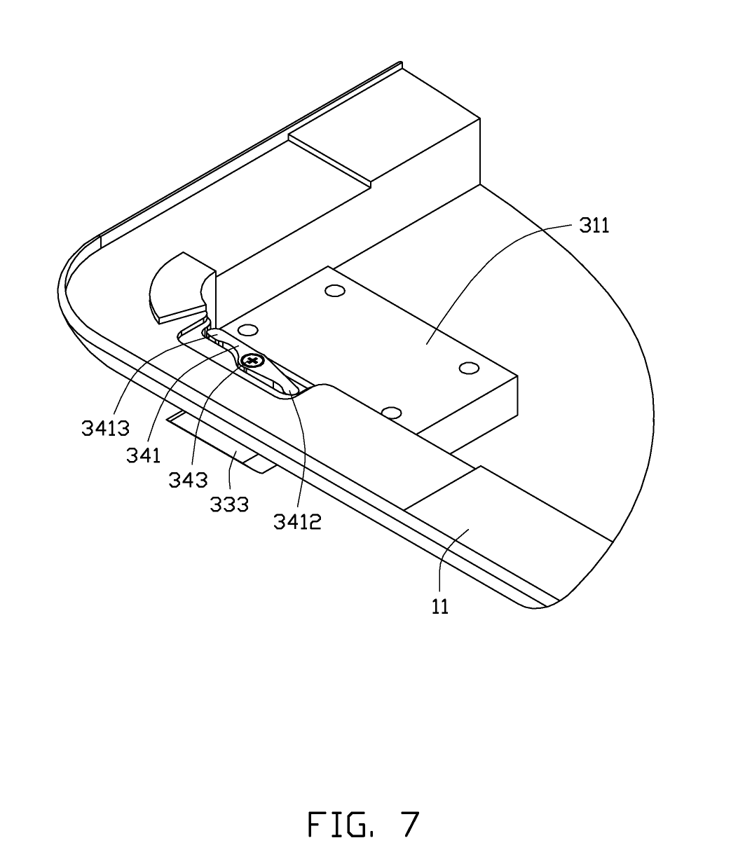

FIGS. 5 through 7 show that in use, when the chip card needs to be removed, an amount of pushing force is applied to the pressing portion 3511 of the pushing member 351. The pushing member 351 moves towards the rotating member 341, and the pushing portion 3513 pushes the transferring end 3413 to move towards the fastening member 311. The rotating member 341 rotates around the positioning shaft 343, and the resisting end 3412 moves away from the fastening member 311. The resisting end 3412 resists the resisting surface 3331 of the operating portion 333, and thus the tray 33 is pushed from the insert opening 110 (see FIGS. 5 and 7). A pulling force may be applied to the operating portion 333, thus to pull the tray 33 from the insert opening 110, and the chip card is conveniently taken out from the chip card receiving groove 3315. When a pushing force being applied to the pushing member 351 is stopped, the elastic member 353 forces the pushing member 351 to move back to its original position. When the tray 33 needs to be placed back to the housing 10, a push force is applied to the operating portion 333, and thus the resisting surface 3331 resists the rotation of the resisting end 3412. The tray 33 moves towards the fastening member 311 until the elastic latching members 313 latch with the tray 33.

It is believed that the present embodiments and their advantages will be understood from the foregoing description, and it will be apparent that various changes may be made thereto without departing from the spirit and scope of the embodiments or sacrificing all of its material advantages.

What is claimed is:

1. An electronic device, comprising:
a housing defining an insert opening; and
a chip card holding mechanism, comprising:
a tray received in the insert opening, and comprising a base body for receiving a chip card and an operating portion located at an end of the base body, the operating portion comprising a resisting surface at one end thereof adjacent to the base body,
a transferring assembly mounted on the housing, and comprising a rotating member and a positioning shaft, wherein the positioning shaft is securely positioned on the housing, the rotating member is rotatably sleeved on the positioning shaft, the rotating member comprises a transferring end and a resisting end opposite to the transferring end, and
a driving assembly mounted on the housing, and resisting the transferring end of the rotating member,
wherein the resisting end of the rotating member resists the resisting surface of the operating portion, when the driving assembly is pushed towards the rotating member, and then drives the rotating member to rotate around the positioning shaft by pushing the transferring end of the rotating member, the resisting end resists the resisting surface to drive the tray to move relative to the housing, and the tray thereby slides out from the insert opening.

2. The electronic device of claim 1, wherein the housing defines a restricting hole, the rotating member defines an insert hole therein, the positioning shaft is inserted into the insert hole and the restricting hole.

3. The electronic device of claim 1, wherein the housing further defines a receiving groove at an outer sidewall thereof, the driving assembly comprises a pushing member and an elastic member sleeved on the pushing member, the pushing member and the elastic member are received in the receiving groove, the pushing member resists the transferring end of the rotating member.

4. The electronic device of claim 3, wherein the pushing member comprises a pressing portion, a pushing portion and at least one positioning portion, the pushing portion and the positioning portion protrude from the pressing portion, a bottom wall of the receiving groove defines a through hole and a positioning hole, the at least one positioning portion is inserted into the positioning hole to position the pushing member into the receiving groove, the elastic member is sleeved on the pushing portion, the pushing portion passes through the through hole and resists the transferring end of the rotating member.

5. The electronic device of claim 4, wherein two ends of the elastic member resist the pressing portion and the bottom wall of the receiving groove.

6. The electronic device of claim 4, wherein the at least one positioning portion defines an opening at an end away from the pressing portion, two posts protrude from an outer sidewall of the positioning portion, the posts resist an inner sidewall of the positioning hole.

7. The electronic device of claim 1, wherein the chip card holding mechanism further comprises a latching assembly, the latching assembly comprises a fastening member and a pair of elastic latching members, the fastening member is fixed on the housing, and defines a containing groove therein, the pair of elastic latching members are fixed within the containing groove of the fastening member, and are latched with the tray.

8. The electronic device of claim 7, wherein the base body defines a pair of latching grooves at two opposite sides, each of the pair of the elastic latching members comprises a latching portion, the latching portion is latched with one of the latching grooves.

9. The electronic device of claim 1, wherein an inner sidewall of the housing defines a indent, the indent communicates with the insert opening, a protruding portion protrude outward from a sidewall of the indent, the restricting hole is defined on the protruding portion, the rotating member is positioned on the protruding portion.

10. The electronic device of claim 9, wherein the protruding portion comprises a first protruding portion and a second protruding portion, the first protruding portion and the second protruding portion protrude along a direction perpendicular to an inner sidewall of the housing, the first protruding portion is located above the insert opening, and the second protruding portion is located above the first protruding portion, the rotating member is positioned on the first protruding portion, and the positioning shaft is positioned on the first protruding portion.

11. The electronic device of claim 10, wherein the first protruding portion defines a restricting hole, the positioning shaft passes through the rotating member and fixed in the restricting hole.

12. A chip card holding mechanism, comprising:
a tray received in the insert opening, and comprising a base body for receiving a chip card and an operating portion located at an end of the base body, the operating portion comprising a resisting surface at one end thereof adjacent to the base body,
a transferring assembly comprising a rotating member and a positioning shaft, wherein the rotating member is rotatably sleeved on the positioning shaft, the rotating member comprises a transferring end and a resisting end opposite to the transferring end, and
a driving assembly resisting the transferring end of the rotating member,
wherein the resisting end resists the resisting surface, when the driving assembly is pushed towards the rotating member, and then drives the rotating member to rotate around the positioning shaft by pushing the transferring end, the resisting end resists the resisting surface to drive the tray to move.

13. The chip card holding mechanism of claim 12, wherein the rotating member defines an insert hole therein, the positioning shaft is inserted into the insert hole.

14. The chip card holding mechanism of claim 12, wherein the driving assembly comprises a pushing member and an elastic member sleeved on the pushing member, the pushing member resists the transferring end of the rotating member.

15. The chip card holding mechanism of claim 14, wherein the pushing member comprises a pressing portion, a pushing portion and a positioning portion, the pushing portion and the positioning portion protrude from the pressing portion, the elastic member is sleeved on the pushing portion, the pushing portion resists the transferring end.

16. The chip card holding mechanism of claim 15, wherein the elastic member resist the pressing portion.

17. The chip card holding mechanism of claim 15, wherein the positioning portion defines an opening at an end thereof away from the pressing portion, two posts protrude from an outer sidewall of the positioning portion.

18. The chip card holding mechanism of claim 12, wherein the chip card holding mechanism further comprises a latching assembly, the latching assembly comprises a fastening member and a pair of elastic latching members, the fastening member defines a containing groove thereon, the pair of elastic latching members are fixed within the containing groove of the fastening member, and are latched with the tray.

19. The chip card holding mechanism of claim 18, wherein the main body defines a pair of latching grooves at two opposite sides, each of the pair of the elastic latching member comprises a latching portion, the latching portion is latched with one of the latching grooves.

20. The chip card holding mechanism of claim 12, wherein the base body defines a chip card receiving groove thereon, for receiving a chip card.
